(19) United States
(12) Patent Application Publication
(10) Pub. No.: US 2024/0206287 A1
(43) Pub. Date: Jun. 20, 2024

(54) DISPLAY DEVICE

(71) Applicant: LG Display Co., Ltd., Seoul (KR)

(72) Inventors: DongHyun PARK, Incheon (KR); Kyuwon KYOUNG, Seoul (KR)

(73) Assignee: LG Display Co., Ltd., Seoul (KR)

(21) Appl. No.: 18/527,430

(22) Filed: Dec. 4, 2023

(30) Foreign Application Priority Data
Dec. 15, 2022 (KR) 10-2022-0175713

(51) Int. Cl. H10K 59/80; H10K 59/19; H10K 59/40; H10K 71/13; H10K 85/10

(52) U.S. Cl. CPC H10K 59/8731; H10K 59/19; H10K 59/40; H10K 71/135; H10K 85/111

(57) ABSTRACT

According to an aspect of the present disclosure, a display device includes a substrate including an active area and a non-active area surrounding the active area; a light emitting element in the active area; an encapsulation unit covering the light emitting element; a first organic layer disposed along a circumference of the substrate on the encapsulation unit in the non-active area; and a second organic layer covering the encapsulation unit and the first organic layer. Therefore, display quality of the display device may be improved.

### CROSS-REFERENCE TO RELATED APPLICATIONS

This application claims the benefit of and priority to Korean Patent Application No. 10-2022-0175713 filed on Dec. 15, 2022, in the Republic of Korea, the entire contents of which are hereby expressly incorporated by reference into the present application.

### BACKGROUND

### Technical Field

The present disclosure relates to a display device, and more particularly, to a display device capable of improving display quality.

### Discussion of the Related Art

Recently, as our society advances toward an information-oriented society, the field of display devices for visually expressing an electrical information signal has rapidly advanced. Various display devices having excellent performance in terms of thinness, lightness, and low power consumption, are being developed.

Among these various display devices, a self-light emitting display device, and may be manufactured to be light and thin since it does not require a separate light source, unlike a liquid crystal display device having a separate light source. In addition, the light emitting display device has advantages in terms of power consumption due to a low voltage operation, and is excellent in terms of a color implementation, a response speed, a viewing angle, and a contrast ratio (CR). Therefore, light emitting display devices have been studied as the next generation displays.

### SUMMARY

An aspect of the present disclosure is to provide a display device capable of improving flatness.

Another aspect of the present disclosure is to provide a display device capable of preventing spots.

Objects of the present disclosure are not limited to the above-mentioned objects, and other objects, which are not mentioned above, may be clearly understood by those skilled in the art from the following descriptions.

A display device according to an exemplary aspect of the present disclosure includes a substrate including an active area and a non-active area surrounding the active area; a light emitting element in the active area; an encapsulation unit covering the light emitting element; a first organic layer disposed along a circumference of the substrate on the encapsulation unit in the non-active area; and a second organic layer covering the encapsulation unit and the first organic layer.

Other detailed matters of the exemplary aspects are included in the detailed description and the drawings.

According to the present disclosure, a step in an outer portion of a display device may be alleviated by disposing an organic layer in an outermost portion of a substrate.

According to the present disclosure, display quality of a display device may be improved by improving flatness of the display device.

The effects according to the present disclosure are not limited to the contents exemplified above, and more various effects are included in the present specification.

### BRIEF DESCRIPTION OF THE DRAWINGS

FIG. 1 is a schematic plan view of a display device according to an exemplary aspect of the present disclosure.

FIG. 2 is a cross-sectional view of II-II′ of FIG. 1.

FIG. 3 is a cross-sectional view of III-III′ of FIG. 1.

FIG. 4 is a schematic cross-sectional view illustrating a method of manufacturing a display device according to an exemplary aspect of the present disclosure.

FIG. 5 is a schematic plan view of a display device according to another exemplary aspect of the present disclosure. FIG. 6 is a cross-sectional view taken along line VI-VI′ of FIG. 5.

### DETAILED DESCRIPTION

Advantages and characteristics of the present disclosure and a method of achieving the advantages and characteristics will be clear by referring to exemplary aspects described below in detail together with the accompanying drawings. However, the present disclosure is not limited to the exemplary aspects disclosed herein but will be implemented in various forms. The exemplary aspects are provided by way of example only so that those skilled in the art may fully understand the disclosures of the present disclosure and the scope of the present disclosure.

The shapes, sizes, ratios, angles, numbers, and the like illustrated in the accompanying drawings for describing the exemplary aspects of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various aspects of the present disclosure may be partially or entirely adhered to or combined with each other and may be interlocked and operated in technically various ways, and the aspects may be carried out independently of or in association with each other.

Hereinafter, the present disclosure will be described in detail with reference to accompanying drawings.

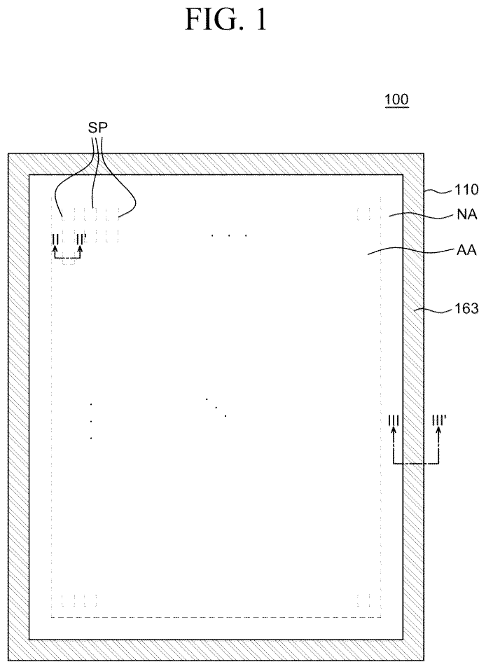

FIG. 1 is a schematic plan view of a display device according to an exemplary aspect of the present disclosure. In FIG. 1, a substrate 110 and a first organic layer 163 among components of a display device 100 are briefly illustrated for convenience of explanation.

Referring to FIG. 1, the display device 100 includes the substrate 110 and the first organic layer 163.

The substrate 110 is a support member for supporting other components of the display device 100. The substrate 110 includes an active area AA and a non-active area NA. The substrate 110 may be formed of an insulating material. For example, the substrate 110 may be formed of glass or resin. In addition, the substrate 110 may be formed of a polymer or plastic such as polyimide (PI) or may be formed of a flexible material.

The active area AA is configured to display an image. A plurality of sub-pixels SP for displaying an image and a driving circuit for driving the plurality of sub-pixels SP may be disposed in the active area AA. Each of the plurality of sub-pixels SP is an individual unit that emits light, and a light emitting element 140 to be described below may be disposed in each of the plurality of sub-pixels SP. The plurality of sub-pixels SP may include a red sub-pixel, a green sub-pixel, a blue sub-pixel, and a white sub-pixel, but are not limited thereto. Non-limiting components of a driving circuit may include various transistors, storage capacitors, lines, and the like for driving the plurality of sub-pixels. In one non-limiting example, the driving circuit may include various components such as a driving transistor, a switching transistor, a sensing transistor, a storage capacitor, gate lines, and data lines, but the present disclosure is not limited thereto.

The non-active area NA is disposed to surround the active area AA does not display an image. The non-active area NA includes various lines, pads, driver integrated circuits (ICs), and the like for driving the plurality of sub-pixels SP disposed in the active area AA. For example, various driver ICs such as a gate driver and a data driver may be disposed in the non-active area NA.

The first organic layer 163 is disposed in the non-active area NA. In particular, the first organic layer 163 may be disposed in an outermost portion of the non-active area NA. The first organic layer 163 may be continuously disposed along a circumference of the substrate 110. In some cases, an end portion of the first organic layer 163 may be disposed on the same plane as an end portion of the substrate 110. For example, the first organic layer 163 may be formed of photo acrylic. In some aspects, the first organic layer 163 may improve flatness of the display device 100. This will be described later.

In some aspects, a plurality of first touch electrodes 171 and a plurality of second touch electrodes 172, which will be described later, may be disposed in the active area AA. The plurality of first touch electrodes 171 and the plurality of second touch electrodes 172 may sense a touch input to the display device 100. In this case, the touch input may be an input by a user's finger or a touch pen. When a touch operation is performed on a specific area of the display device 100, a change in capacitance may occur between the first touch electrodes 171 and the second touch electrodes 172 adjacent to the specific area. The display device 100 may detect touch coordinates by sensing the change in capacitance.

The plurality of first touch electrodes 171 may extend in a first direction, and the plurality of second touch electrodes 172 may extend in a second direction. In this case, the plurality of first touch electrodes 171 and the plurality of second touch electrodes 172 may be disposed such that portions thereof cross each other. That is, the plurality of first touch electrodes 171 and the plurality of second touch electrodes 172 may be disposed to partially overlap each other. The plurality of first touch electrodes 171 may be continuously formed in the first direction without being disconnected. The plurality of respective second touch electrodes 172 are formed to be separated in areas thereof overlapping the plurality of first touch electrodes 171. Also, the separated second touch electrodes 172 may be connected by bridge electrodes 173.

The plurality of first touch electrodes 171 and the plurality of second touch electrodes 172 may have a metal mesh structure. In one aspect, the plurality of first touch electrodes 171 and the plurality of second touch electrodes 172 may include mesh patterns formed by crossing metal lines having a very thin width. Openings formed in the mesh patterns may correspond to the plurality of sub-pixels SP. In this case, the openings may refer to spaces that have no metal lines disposed therein and are surrounded by metal lines. The mesh patterns may have diamond shapes, but are not limited thereto. The mesh patterns may have a single layer or multilayer structure formed of a metal material. Non-limiting examples of a metal material includes metals such as molybdenum (Mo), silver (Ag), titanium (Ti), copper (Cu), aluminum (Ti), titanium/aluminum/titanium (Ti/Al/Ti), or molybdenum/aluminum/molybdenum (Mo/Al/Mo), and so forth.

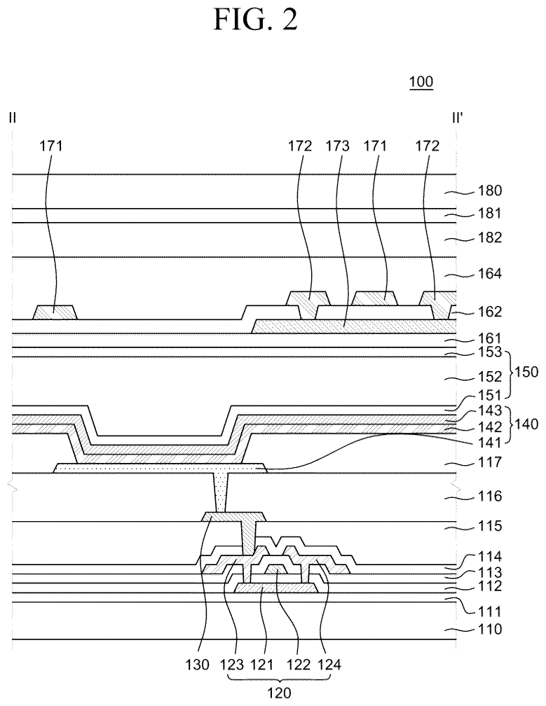

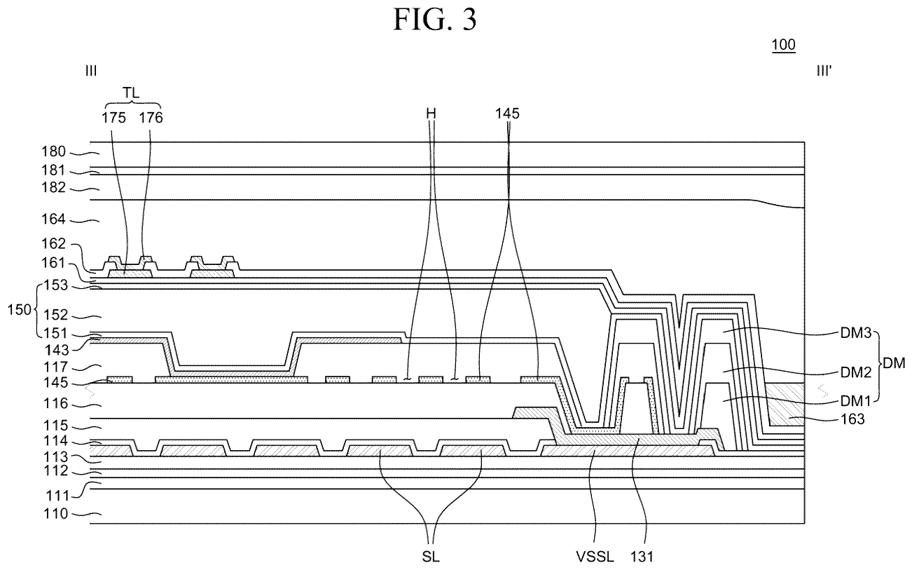

Hereinafter, a detailed structure of one sub-pixel SP will be described with reference to FIG. 2.

FIG. 2 is a cross-sectional view of II-II′ of FIG. 1.

Referring to FIG. 2, the display device 100 includes the substrate 110, a transistor 120, the light emitting element 140, an encapsulation unit 150, the first touch electrodes 171, the second touch electrodes 172, a second organic layer 164, a polarizing plate 181, and a cover window 180.

A first buffer layer 111 is disposed on the substrate 110. The first buffer layer 111 may reduce penetration of moisture or impurities through the substrate 110. In addition, the first buffer layer 111 may protect the transistor 120 from impurities such as alkali ions flowing out of the substrate 110. In addition, the first buffer layer 111 may improve adhesion between layers formed thereon and the substrate 110. The first buffer layer 111 may be formed of, for example, a single layer or multiple layers of silicon oxide (SiOx) or silicon nitride (SiNx), but is not limited thereto.

The transistor 120 disposed on the first buffer layer 111 may be configured to drive the light emitting element 140. The transistor 120 may include an active layer 121, a gate electrode 122, a source electrode 123, and a drain electrode 124.

The active layer 121 is disposed on the first buffer layer 111 and forms a channel when the transistor 120 is driven. The active layer 121 may include a channel region, a source region, and a drain region. The active layer 121 may be formed of a semiconductor material. Non-limiting examples of a semiconductor material includes an oxide semiconductor, amorphous silicon, or polysilicon, and so forth.

A gate insulating layer 112 is disposed on the active layer 121. The gate insulating layer 112 may insulate the active layer 121 and the gate electrode 122. Contact holes for respectively connecting the source electrode 123 and the drain electrode 124 to the active layer 121 may be formed in the gate insulating layer 112. The gate insulating layer 112 may be formed of a single layer or multiple layers of silicon oxide (SiOx) or silicon nitride (SiNx), but is not limited thereto.

The gate electrode 122 is disposed on the gate insulating layer 112. The gate electrode 122 is disposed on the gate insulating layer 112 to overlap the channel region of the active layer 121. The gate electrode 122 may be formed of a conductive material, such as copper (Cu), aluminum (Al), molybdenum (Mo), nickel (Ni), titanium (Ti), chromium (Cr), or an alloy thereof, but is not limited thereto.

A first interlayer insulating layer 113 is disposed on the gate electrode 122. Contact holes for respectively connecting the source electrode 123 and the drain electrode 124 to the active layer 121 are formed in the first interlayer insulating layer 113. The first interlayer insulating layer 113 may be formed of a single layer or multiple layers of silicon oxide (SiOx) or silicon nitride (SiNx), but is not limited thereto.

The source electrode 123 and the drain electrode 124 are disposed on the first interlayer insulating layer 113 to be separated from each other. The source electrode 123 and the drain electrode 124 are electrically connected to the active layer 121 through the contact holes of the gate insulating layer 112 and the first interlayer insulating layer 113. The source electrode 123 and the drain electrode 124 may be formed of a conductive material, such as copper (Cu), aluminum (Al), molybdenum (Mo), nickel (Ni), titanium (Ti), chromium (Cr), or an alloy thereof, but the present disclosure is not limited thereto.

A passivation layer 114 is disposed on the transistor 120. The passivation layer 114 may insulate the transistor 120 and components thereon. The passivation layer 114 may be formed of a single layer or multiple layers of silicon oxide (SiOx) or silicon nitride (SiNx), but is not limited thereto.

A first planarization layer 115 and a second planarization layer 116 are disposed on the passivation layer 114. The first planarization layer 115 and the second planarization layer 116 are insulating layers that planarize an upper portion of the substrate 110. The first planarization layer 115 may include a contact hole for electrically connecting the transistor 120 and a first auxiliary electrode 130 to each other. In one aspect, the first planarization layer 115 may include a contact hole exposing either one of the source electrode 123 and the drain electrode 124 of the transistor 120. The second planarization layer 116 may include a contact hole for electrically connecting the first auxiliary electrode 130 to an anode 141. The first planarization layer 115 and the second planarization layer 116 may be formed of an organic material, for example, may be formed of a single layer or multilayers of polyimide or photo acrylic, but the present disclosure is not limited thereto.

The first auxiliary electrode 130 is disposed between the first planarization layer 115 and the second planarization layer 116. The first auxiliary electrode 130 may connect the source electrode 123 of the transistor 120 and the anode 141 of the light emitting element 140. Although the first auxiliary electrode 130 is illustrated as being connected to the source electrode 123 in FIG. 2, the first auxiliary electrode 130 may be connected to the drain electrode 124. The first auxiliary electrode 130 may be formed of a conductive material. Non-limiting examples of a conductive metal include copper (Cu), aluminum (Al), molybdenum (Mo), nickel (Ni), titanium (Ti), chromium (Cr), or an alloy thereof, and so forth.

The light emitting element 140 is disposed on the second planarization layer 116. The light emitting element 140 includes the anode 141, an organic layer 142, and a cathode 143.

In some cases, the display device 100 may be implemented as a top emission type or a bottom emission type. In the case of the top emission type, a reflective layer for reflecting light emitted from the organic layer 142 toward the cathode 143 may be disposed under the anode 141. For example, the reflective layer may include a material having excellent reflectivity such as aluminum (Al) or silver (Ag), but is not limited thereto. Conversely, in the case of the bottom emission type, the anode 141 may be formed of only a transparent conductive material. Hereinafter, descriptions are made assuming that the display device 100 according to an exemplary aspect of the present disclosure is the top emission type.

The anode 141 is disposed on the second planarization layer 116. The anode 141 may correspond to each of the plurality of sub-pixels SP. The anode 141 may be patterned to correspond to each individual sub-pixel of the plurality of sub-pixels. The anode 141 may be electrically connected to the first auxiliary electrode 130 and the source electrode 123 of the transistor 120 through the contact holes formed in the second planarization layer 116 and the first planarization layer 115. The anode 141 may be formed of a conductive material having a high work function to supply holes to the organic layer 142. For example, the anode 141 may be formed of a transparent conductive material, such as indium tin oxide (ITO) or indium zinc oxide (IZO), but is not limited thereto.

A bank 117 is disposed on the anode 141 and the second planarization layer 116. The bank 117 may be formed on the second planarization layer 116 to cover an edge of the anode 141. The bank 117 is an insulating layer disposed between the plurality of sub-pixels to distinguish the plurality of sub-pixels. The bank 117 may be an organic insulating material. For example, the bank 117 may be formed of polyimide, acryl, or benzocyclobutene (BCB)-based resin, but is not limited thereto.

The organic layer 142 is disposed on the anode 141 and the bank 117. The organic layer 142 may be formed as a single layer over an entire surface of the substrate 110. That is, the organic layer 142 may be a common layer commonly formed in the plurality of sub-pixels SP, but is not limited thereto. The organic layer 142 may be an organic layer for emitting light of a specific color. For example, the organic layer 142 may be one of a red light emitting layer, a green light emitting layer, a blue light emitting layer, and a white light emitting layer. When the organic layer 142 is formed of a white light emitting layer, a color filter may be further disposed on the light emitting element 140. The organic layer 142 may include various layers such as a light emitting layer, a hole transport layer, a hole injection layer, a hole blocking layer, an electron injection layer, an electron blocking layer, an electron transport layer, and the like.

The cathode 143 is disposed on the organic layer 142. The cathode 143 may be formed as a single layer over the entire surface of the substrate 110. That is, the cathode 143 may be a common layer formed in the plurality of sub-pixels SP. Since the cathode 143 supplies electrons to the organic layer 142, it may be formed of a conductive material having a low work function. The cathode 143 may be formed of, for example, a transparent conductive material, such as indium tin oxide (ITO) or indium zinc oxide (IZO), a metal alloy such as MgAg, or an ytterbium (Yb) alloy, and may further include a metal-doped layer, but the present disclosure is not limited thereto.

The encapsulation unit 150 is disposed to cover the light emitting element 140. The encapsulation unit 150 protects the light emitting element 140 from moisture penetrating into the display device 100. The encapsulation unit 150 includes a first encapsulation layer 151, a foreign material cover layer 152, and a second encapsulation layer 153.

The first encapsulation layer 151 may be disposed on the cathode 143 to suppress penetration of moisture or oxygen. The first encapsulation layer 151 may be formed of an inorganic material, such as silicon nitride (SiNx), silicon oxynitride (SiNxOy), or aluminum oxide (AlyOz), but is not limited thereto.

The foreign material cover layer 152 is disposed on the first encapsulation layer 151 to planarize a surface thereof. In addition, the foreign material cover layer 152 may cover foreign material or particles that may occur in a manufacturing process. The foreign material cover layer 152 may be formed of an organic material, such as silicon oxycarbon (SiOxCz), acrylic or epoxy-based resin, but is not limited thereto.

The second encapsulation layer 153 is disposed on the foreign material cover layer 152 and, similar to the first encapsulation layer 151, may suppress penetration of moisture or oxygen. In this case, the second encapsulation layer 153 and the first encapsulation layer 151 may be formed to seal the foreign material cover layer 152. Accordingly, moisture or oxygen penetrating into the light emitting element 140 may be more effectively reduced by the second encapsulation layer 153. The second encapsulation layer 153 may be formed of an inorganic material, such as silicon oxide (SiOx), silicon nitride (SiNx), silicon oxynitride (SiNxOy), or aluminum oxide (AlyOz), but is not limited thereto.

A second buffer layer 161 is disposed on the encapsulation unit 150. The second buffer layer 161 may reduce penetration of moisture or impurities. The second buffer layer 161 may be formed of a single layer or multiple layers of silicon oxide (SiOx) or silicon nitride (SiNx), but is not limited thereto.

The bridge electrodes 173 are disposed on the second buffer layer 161. The bridge electrode 173 may electrically connect the second touch electrodes 172 that are separated from each other. The bridge electrodes 173 may also overlap portions of the first touch electrodes 171. In this case, the bridge electrodes 173 may be formed on a layer different from that of the first touch electrodes 171. For example, the bridge electrodes 173 may be disposed below the first touch electrodes 171 that are continuously formed to electrically connect the separated second touch electrodes 172. Accordingly, the first touch electrodes 171 and the second touch electrodes 172 that are formed to cross each other and may be electrically insulated from each other.

A second interlayer insulating layer 162 is disposed on the second buffer layer 161 and the bridge electrodes 173. The second interlayer insulating layer 162 may electrically insulate the bridge electrode 173 and the first touch electrode 171 from each other. The second interlayer insulating layer 162 may include a contact hole through which the second touch electrode 172 and the bridge electrode 173 are connected to each other. The second interlayer insulating layer 162 may be formed of a single layer or multiple layers of silicon oxide (SiOx) or silicon nitride (SiNx), but is not limited thereto.

The first touch electrode 171 and the second touch electrode 172 may be disposed on the second interlayer insulating layer 162. The first touch electrode 171 and the second touch electrode 172 may be separated from each other by a predetermined distance on the second interlayer insulating layer 162. The first touch electrodes 171 may be formed to continuously extend in the first direction on the second interlayer insulating layer 162. The second touch electrodes 172 may be formed to extend in the second direction on the second interlayer insulating layer 162. The second touch electrodes 172 may be separated in areas that overlap with the first touch electrodes 171. The separated second touch electrodes 172 may be connected by the bridge electrode 173.

The second organic layer 164 may be disposed to cover the first touch electrodes 171, the second touch electrodes 172, and the second interlayer insulating layer 162. The second organic layer 164 may planarize upper portions of the plurality of first touch electrodes 171 and the plurality of second touch electrodes 172. For example, the second organic layer 164 may be configured to entirely planarize upper portions of the active area AA and the non-active area NA on the substrate 110. The second organic layer 164 may be formed of an organic material such as silicon oxycarbon (SiOxCz), acrylic or epoxy-based resin, but is not limited thereto.

An adhesive layer 182 is disposed on the second organic layer 164. The adhesive layer 182 may be configured to bond the second organic layer 164 and the polarizing plate 181. Also, the adhesive layer 182 may be disposed to fill a space between the second organic layer 164 and the polarizing plate 181. The adhesive layer 182 may be a thermal curing, light-curing, pressure-adhesive, or natural curable adhesive. In one aspect, when the adhesive layer 182 has thermal curing properties, flowability of the adhesive layer 182 improves for a certain period of time during high temperature curing, so that the adhesive layer 182 may effectively fill a step difference existing on the second organic layer 164 and flatten an upper portion of the second organic layer 164. However, the present disclosure is not limited thereto. The adhesive layer 182 may be formed of optical clear adhesive (OCA), optical clear resin (OCR), pressure sensitive adhesive (PSA), or the like, but is not limited thereto.

The polarizing plate 181 is disposed on the adhesive layer 182. The polarizing plate 181 may selectively transmit light and reduce reflection of external light incident on the display device 100. In one aspect, the display device 100 includes various metal materials applied to semiconductor elements, lines, light emitting elements, and the like. External light incident on the display device 100 may be reflected by the metal material and visibility of the display device 100 may be reduced due to the reflection of the external light. In this case, the visibility of the display device 100 may be improved by including the polarizing plate 181 to prevent reflection of external light.

The cover window 180 is disposed on the polarizing plate 181. The cover window 180 may be exposed from an outer portion of the display device 100 and may protect the display device 100 from external impacts and scratches. In addition, the cover window 180 may protect the display device 100 from moisture or the like that permeates from the outside. The cover window 180 may be formed of glass or a flexible plastic material, but is not limited thereto. In some cases, an adhesive layer may be disposed between the cover window 180 and the polarizing plate 181 to bond the cover window 180 and the polarizing plate 181, but is not limited thereto.

FIG. 3 is a cross-sectional view of III-III′ of FIG. 1.

Referring to FIG. 3, the display device 100 includes a plurality of signal lines SL, a low potential power line VSSL, a second auxiliary electrode 131, a connection electrode 145, touch routing lines TL, and dams DM.

The plurality of signal lines SL are disposed in the non-active area NA. The plurality of signal lines SL may be formed of the same material as one of various conductive elements formed in the active area AA. For example, the plurality of signal lines SL may be disposed on the first interlayer insulating layer 113 and formed of the same material by the same process as the source electrode 123 and the drain electrode 124. However, the present disclosure is not limited thereto. Various driver ICs may be disposed in the non-active area NA and are electrically connected to the plurality of sub-pixels SP of the active area AA and configured to drive the plurality of sub-pixels SP. The plurality of signal lines SL may connect the driver IC to the plurality of sub-pixels SP and transmit driving signals for driving the plurality of sub-pixels SP.

The low potential power line VSSL may be disposed along the circumference of the substrate 110 in the outermost portion of the non-active area NA. The low potential power line VSSL may be formed of the same material as one of various conductive elements formed in the active area AA. For example, the low potential power line VSSL may be disposed on the first interlayer insulating layer 113 and formed of the same material by the same process as the source electrode 123 and the drain electrode 124. However, the present disclosure is not limited thereto. The low potential power line VSSL may be electrically connected to the cathode 143 through the second auxiliary electrode 131 and the connection electrode 145. Accordingly, the low potential power line VSSL may supply a low potential voltage to the cathode 143.

The second auxiliary electrode 131 is disposed on the low potential power line VSSL. The second auxiliary electrode 131 may be formed of the same material as one of various conductive elements formed in the active area AA. For example, a portion of the second auxiliary electrode 131 may be disposed between the first planarization layer 115 and the second planarization layer 116. The second auxiliary electrode 131 may extend on the low potential power line VSSL between the first planarization layer 115 and the second planarization layer 116. The second auxiliary electrode 131 may be formed of the same material by the same process as the first auxiliary electrode 130. However, the present disclosure is not limited thereto.

The connection electrode 145 is disposed on the second planarization layer 116 in the non-active area NA. The connection electrode 145 may be formed of the same material by the same process as the anode 141 but is not limited thereto. The connection electrode 145 may be formed of the same material by the same process as the anode 141 but the present disclosure is not limited thereto. In addition, the connection electrode 145 may be formed entirely on the second planarization layer 116 of the non-active area NA but the present disclosure is not limited thereto. The connection electrode 145 is electrically connected to the cathode 143 in the non-active area NA. In addition, the connection electrode 145 is electrically connected to the low potential power line VSSL by the second auxiliary electrode 131 in the outermost portion of the non-active area NA. Accordingly, the connection electrode 145 may supply a low potential voltage supplied through the low potential power line VSSL to the cathode 143.

The connection electrode 145 may include a plurality of first holes H formed in the connection electrode 145 that eclectically connects the second auxiliary electrode 131 to the cathode 143. Gas may be generated in the first planarization layer 115 or the second planarization layer 116 under the connection electrode 145 during a manufacturing process and may be easily discharged to the outside through the plurality of first holes H. As shown in FIG. 6, the connection electrode extends in a lateral direction and a plurality of holes H cause the connection electrode to appear as discontinuous regions along line VI-VI′, the connection electrode 145 electrically connects the second auxiliary electrode 131 to the cathode 143.

The touch routing lines TL are disposed on the second buffer layer 161 in the non-active area NA. A plurality of the touch routing lines TL may be provided and electrically connected to each of the plurality of first touch electrodes 171 and the plurality of second touch electrodes 172. A first end of the touch routing lines TL may be connected to the plurality of first touch electrodes 171 or the plurality of second touch electrodes 172 and the second end thereof may be connected to corresponding touch pads. Accordingly, the touch routing lines TL may receive a touch signal from the outside or transmit a touch sensing signal to the outside.

The touch routing line TL includes a first line layer 175 and a second line layer 176. The touch routing line TL has a structure in which the first line layer 175 and the second line layer 176 are stacked to reduce resistance of the touch routing lines. The first line layer 175 is disposed on the second buffer layer 161. The first line layer 175 may be formed of the same material by the same process as the bridge electrode 173. The second line layer 176 is disposed on the first line layer 175. The second line layer 176 may be electrically connected to the first line layer 175 through a contact hole formed in the second interlayer insulating layer 162. The second line layer 176 may be formed of the same material by the same process as the first touch electrode 171 and the second touch electrode 172.

The dams DM are disposed in an area adjacent to the end portion of the substrate 110. The dams DM may be disposed to overlap the low potential power line VSSL or the second auxiliary electrode 131 but are not limited thereto. In addition, although FIG. 3 illustrates that two dams DM are provided, the present disclosure is not limited thereto, and the number of dams DM may be changed as needed.

The dams DM may prevent overflow of the foreign material cover layer 152. The dam DM may have a structure in which a first layer DM1, a second layer DM2, and a third layer DM3 are sequentially stacked over each other. The first layer DM1 may be formed of the same material by the same process as the second planarization layer 116. The second layer DM2 may be formed of the same material by the same process as the bank 117. The third layer DM3 may be formed of an organic material, and may be formed of polyimide, acryl, or benzocyclobutene (BCB)-based resin, but is not limited thereto.

The first organic layer 163 may be disposed outside the dams DM. The first organic layer 163 may be disposed on the encapsulation unit 150. In particular, the first encapsulation layer 151 and the second encapsulation layer 153 of the encapsulation unit 150 may be disposed under the first organic layer 163 to be directly in contact with each other. In this case, the first encapsulation layer 151 and the second encapsulation layer 153 may reduce moisture permeation to side surfaces of the display device 100. In addition, the first buffer layer 111, the gate insulating layer 112, the first interlayer insulating layer 113, the passivation layer 114, the second buffer layer 161, and the second interlayer insulating layer 162 may be further disposed under the first organic layer 163. However, the present disclosure is not limited thereto, and end portions of the first buffer layer 111, the gate insulating layer 112, the first interlayer insulating layer 113, the passivation layer 114, the second buffer layer 161, and the second interlayer insulating layer 162 may be disposed inside the first organic layer 163.

The second organic layer 164 is disposed on the plurality of touch routing lines TL and the second interlayer insulating layer 162 in the non-active area NA. In addition, the second organic layer 164 is disposed on the first organic layer 163 outside the dams DM. The second organic layer 164 may be configured to entirely planarize upper portions of the active area AA and the non-active area NA.

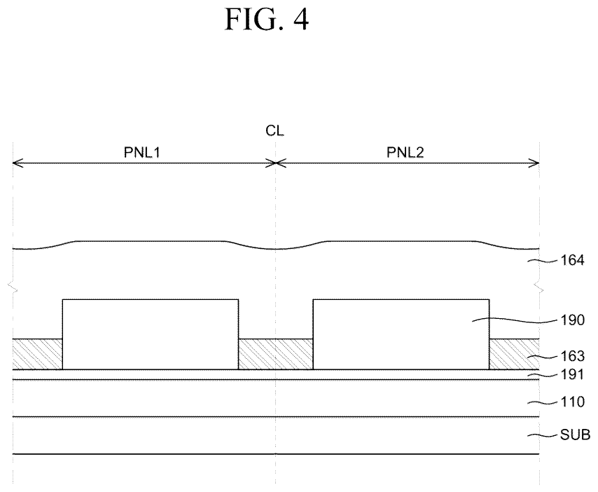

An end portion of the first organic layer 163 and an end portion of the second organic layer 164 may be disposed on the same plane as the end portion of the substrate 110. In some aspects, the display device 100 is manufactured by forming a plurality of panels on one temporary substrate and separating the plurality of panels. When separating the plurality of panels, the substrate 110, the first organic layer 163, and the second organic layer 164 are cut together therewith. Thus, the end portion of the substrate 110, the end portion of the first organic layer 163, and the end portion of the second organic layer 164 may be disposed on the same plane. Hereinafter, a manufacturing process of the display device 100 will be described in detail with reference to FIG. 4.

FIG. 4 is a schematic cross-sectional view illustrating a method of manufacturing a display device according to an exemplary aspect of the present disclosure.

Referring to FIG. 4, a first panel PNL1 and a second panel PNL2 are formed on a temporary substrate SUB. Although only two panels PNL1 and PNL2 are illustrated in FIG. 4, substantially more panels may be formed on the temporary substrate SUB.

Each of the first panel PNL1 and the second panel PNL2 includes the substrate 110, an inorganic layer 191, a display unit 190, the first organic layer 163, and the second organic layer 164. In this case, the inorganic layer 191 includes inorganic insulating layers such as the first buffer layer 111, the gate insulating layer 112, the first interlayer insulating layer 113, the passivation layer 114, the first encapsulation layer 151, the second encapsulation layer 153, the second buffer layer 161, and the second interlayer insulating layer 162. In addition, the display unit 190 may include components of the display device 100, such as the transistor 120, the first auxiliary electrode 130, the light emitting element 140, the first touch electrodes 171, the second touch electrodes 172, the bridge electrodes 173, and the signal lines SL, the low potential power line VSSL, the second auxiliary electrode 131, the connection electrode 145, the touch routing lines TL, and the dams DM.

First, the substrate 110, the inorganic layer 191, and the display unit 190 are formed on the temporary substrate SUB. In this case, the dams DM may be disposed outside the first panel PNL1 and the second panel PNL2, and the foreign material cover layer 152 of the encapsulation unit 150 may be formed inside the dams DM. The foreign material cover layer 152 may be formed to have a thickness of approximately 8 μm to 12 μm through an inkjet printing method. A step between the display unit 190 of the first panel PNL1 and the display unit 190 of the second panel PNL2 exists due to various components of the display unit 190 and the thickness of the foreign material cover layer 152. In other words, a step may exist between an area where the inorganic layer 191 exists outside of the display unit 190. For example, an area between adjacent display units 190, in which only the inorganic layer 191 is disposed and steps occur, which is referred to as a stepped area.

Next, the first organic layer 163 is formed outside the display unit 190. For example, the first organic layer 163 may be formed outside the dams DM. In addition, the first organic layer 163 may be disposed on the first encapsulation layer 151 and the second encapsulation layer 153 of the encapsulation unit 150 and extend outside of the dams DM. In this case, the first organic layer 163 may be formed to have a thickness of approximately 2 μm to 3 μm using an exposure process. The first organic layer 163 is formed through an exposure process and the first organic layer 163 may be easily formed only on a partial area between the adjacent display units 190. In this case, the first organic layer 163 is formed only on the stepped area.

Thereafter, the second organic layer 164 is entirely formed over the display units 190 and the first organic layer 163. The second organic layer 164 may be formed to have a thickness of approximately 8 μm to 12 μm using an inkjet printing method. The second organic layer 164 may be formed on the display units 190 and the first organic layer 163 while filling the stepped area. For example, the first organic layer 163 primarily fills the stepped area and improves the flatness of the second organic layer 164. Accordingly, a step in the outside of each of the first panel PNL1 and the second panel PNL2 may be reduced and it is possible to prevent spots (or stains or mura) from being visually recognized due to the steps.

Next, the polarizing plate 181 may be formed over the second organic layer 164. In this case, the second organic layer 164 and the polarizing plate 181 may be attached by the adhesive layer 182. The adhesive layer 182 may fill minute steps that may occur in the second organic layer 164, and further flatten an upper portion of the second organic layer 164.

For example, the display unit 190 includes various organic layers such as the foreign material cover layer 152 as well as various components of the display device 100. Also, due to process characteristics, a thickness of the first organic layer 163 may be smaller than that of the foreign material cover layer 152. That is, even if the first organic layer 163 is formed in the stepped area, a step may exist between the display unit 190 and the first organic layer 163 of the stepped area. In this case, even if the second organic layer 164 fills the stepped area, a fine step may exist between the second organic layer 164 over the display unit 190 and the second organic layer 164 over the first organic layer 163. However, the fine step may be a step that may be sufficiently compensated by the adhesive layer 182. Accordingly, an upper portion of the display device 100 may be flattened by filling the fine step with the adhesive layer 182.

After forming the polarizing plate 181, the first panel PNL1 and the second panel PNL2 are separated along a cutting line CL. Thereafter, the display device 100 may be manufactured by forming the cover window 180 over the polarizing plate 181.

A step may exist between a central portion and an outer portion of a general display device due to a difference in height therebetween. Specifically, transistors, a planarization layer, light emitting elements, banks, an encapsulation unit including a foreign material cover layer, touch electrodes, various lines, dams, and various inorganic insulating layers are disposed in an active area and a part of a non-active area adjacent to the active area. In this case, organic insulating layers such as the planarization layer, the banks, the foreign material cover layer, and the dams have thicknesses greater than those of the inorganic insulating layers. Meanwhile, only the inorganic insulating layers exist in an outermost portion of the non-active area corresponding to an outside of the dams. A step occurs between the central portion and the outer portion of the display device, which causes a difference in impression of a color between an inside portion and an outer portion of the active area. The step causes spots (or stains or mura) that may be visually recognized.

The display device 100 according to an exemplary aspect of the present disclosure may include the first organic layer 163 and the second organic layer 164 to improve flatness of the display device 100. The first organic layer 163 and the second organic layer 164 may be disposed on the same plane as the end portion of the substrate 110. That is, the first organic layer 163 and the second organic layer 164 are disposed to cover a step that may exist in the outer portion of the display device 100. Therefore, it is possible to reduce the step on the outer portion of the display device 100 and prevent occurrence of spots (or stains or mura).

The first organic layer 163 is disposed along the circumference of the substrate 110 outside the dams DM. The first organic layer 163 may be formed to partially fill a space between the adjacent display units 190 before separating a plurality of the panels PNL1 and PNL2 into individual panels PNL1 and PNL2. That is, the step of the outer portion of the display device 100 may be alleviated by the first organic layer 163. If the first organic layer 163 is not formed, the second organic layer 164 may not sufficiently compensate for a thickness difference between the inorganic layer 191 and the organic insulating layers of the display unit 190. However, flatness of the second organic layer 164 may be further improved by forming the first organic layer 163 before forming the second organic layer 164.

The second organic layer 164 may be formed to entirely cover the upper portion of the display device 100. That is, the second organic layer 164 may entirely planarize the upper portion of the display device 100. The second organic layer 164 may be formed to entirely cover the plurality of panels PNL1 and PNL2 before separating the plurality of panels PNL1 and PNL2 into individual panels PNL1 and PNL2. In particular, the first organic layer 163 is formed to have a certain thickness between the adjacent display units 190. Accordingly, the second organic layer 164 may sufficiently compensate for a step between the display unit 190 and the first organic layer 163 and planarize the upper portion of the substrate 110.

The first organic layer 163 and the second organic layer 164 may be formed of different materials by different processes. For example, the first organic layer 163 may be formed by patterning photo-reactive photo acrylic using an exposure process. The second organic layer 164 may be formed by applying silicon oxycarbon, acrylic, or epoxy-based resin having flowability, using an inkjet printing method. Due to process characteristics, the first organic layer 163 may be formed to have a thickness smaller than that of the second organic layer 164. The first organic layer 163 may be locally formed only in a desired area as compared to the second organic layer 164. Accordingly, the first organic layer 163 may be configured to primarily alleviate a step between the display unit 190 and the inorganic layer 191. In addition, the upper portion of the display unit 190 may be flattened by entirely applying the second organic layer 164 having good flowability onto the display unit 190 and the first organic layer 163.

In the display device 100 according to an exemplary aspect of the present disclosure, adhesion between the polarizing plate 181 and the cover window 180 may be improved. For example, by attaching the polarizing plate 181 to the second organic layer 164 that is flattened, adhesion between the polarizing plate 181 and the second organic layer 164 may be increased. In this case, the adhesive layer 182 may be disposed between the polarizing plate 181 and the second organic layer 164. In the display device 100 according to an exemplary aspect of the present disclosure, since the first organic layer 163 is disposed outside the dams DM, there is almost no step in the second organic layer 164 in the outer portion of the display device 100. Even if a fine step exists on an outer portion of the second organic layer 164, the adhesive layer 182 may fill the fine step difference. That is, the adhesive layer 182 and the second organic layer 164 may be completely adhered and attached to each other. Accordingly, even when an external impact is applied to the display device 100, the polarizing plate 181 and the cover window 180 are prevented from being separated from the second organic layer 164. In this case, the durability and quality of the display device 100 may be improved.

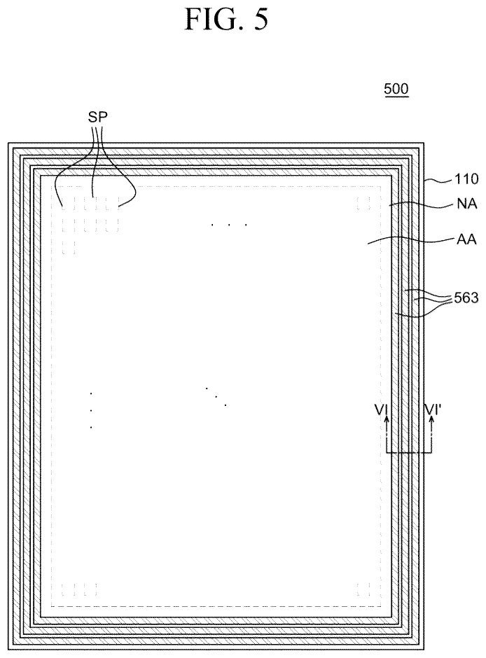

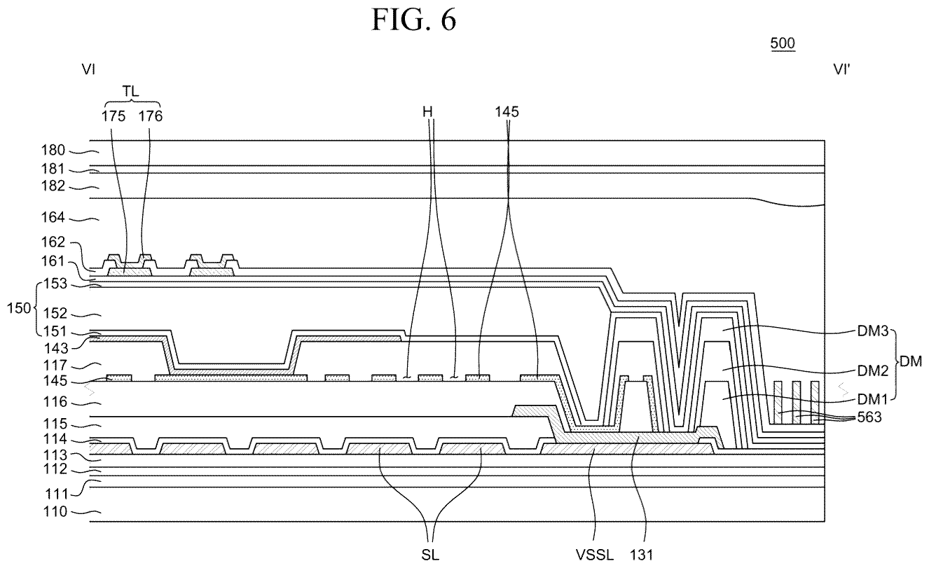

FIG. 5 is a schematic plan view of a display device according to another exemplary aspect of the present specification. FIG. 6 is a cross-sectional view taken along line VI-VI′ of FIG. 5. In FIG. 5, only the substrate 110 and organic patterns 563 among components of a display device 500 are briefly illustrated for convenience of description. Since the display device 500 of FIG. 5 is different from the display device 100 of FIGS. 1 to 4 only in terms of the organic patterns 563, redundant descriptions will be omitted.

Referring to FIGS. 5 and 6, the first organic layer of the display device 500 includes a plurality of the organic patterns 563. The plurality of organic patterns 563 are disposed to be separated from each other in the outer portion of the non-active area NA. Each of the plurality of organic patterns 563 may be continuously disposed along the circumference of the substrate 110. The plurality of organic patterns 563 may be disposed outside the dams DM. In some aspects, the plurality of organic patterns 563 may improve flatness in an outer portion of the display device 500.

An end portion of the organic pattern 563 disposed at an outermost portion among the plurality of organic patterns 563 may be disposed inside the end portion of the substrate 110. However, the present disclosure is not limited thereto, and the end portion of the outermost organic pattern 563 may be disposed on the same plane as the end portion of the substrate 110 according to a position of the cutting line CL. The plurality of organic patterns 563 may be formed by patterning photo acrylic using an exposure process. Although three organic patterns 563 are illustrated in FIG. 6, the present disclosure is not limited thereto.

The second organic layer 164 is disposed to cover the first touch electrodes 171, the second touch electrodes 172, and the touch routing lines TL disposed on the encapsulation unit 150. The second organic layer 164 is also disposed on the plurality of organic patterns 563 outside the dams DM. The second organic layer 164 may be configured to entirely planarize upper portions of the active area AA and the non-active area NA. Also, the end portion of the second organic layer 164 may be disposed on the same plane as the end portion of the substrate 110.

In particular, the second organic layer 164 may be formed to fill gaps between the plurality of organic patterns 563. Accordingly, a contact area between the plurality of organic patterns 563 and the second organic layer 164 may be increased. In this case, adhesion between the plurality of organic patterns 563 and the second organic layer 164 may be increased. In addition, moisture penetration into side surfaces of the display device 500 may be delayed as much as possible.

The display device 500 according to another exemplary aspect of the present disclosure may improve flatness of the display device 500 by including the plurality of organic patterns 563 and the second organic layer 164. For example, the plurality of organic patterns 563 are disposed along the circumference of the substrate 110 outside the dams DM. A step in an outer portion of the display device 500 may be primarily alleviated by the plurality of organic patterns 563. The second organic layer 164 is entirely disposed over the display device 500. In particular, since the plurality of organic patterns 563 are disposed outside the dams DM, a step between an inside of the dams DM and the outside of the dams DM may be minimized. Accordingly, flatness of an upper portion of the display device 500 may be improved, and occurrence of spots (or stains or mura) due to the step may be prevented.

The second organic layer 164 may be formed to fill gaps between the plurality of organic patterns 563 separated from each other. That is, as the contact area between the second organic layer 164 and the plurality of organic patterns 563 is increased, adhesion between the second organic layer 164 and the plurality of organic patterns 563 may be improved. Therefore, even when an impact is applied to the display device 500, the second organic layer 164 and the plurality of organic patterns 563 are prevented from separating from an end portion of the display device 500. In addition, as moisture permeation paths to the side surfaces of the display device 500 are increased, moisture permeation may be delayed. Accordingly, durability of the display device 500 may be increased and quality of the display device 500 may be improved.

The exemplary aspects of the present disclosure may also be described as follows:
According to an aspect of the present disclosure, a display device includes a substrate including an active area and a non-active area surrounding the active area; a light emitting element in the active area; an encapsulation unit covering the light emitting element; a first organic layer disposed along a circumference of the substrate on the encapsulation unit in the non-active area; and a second organic layer covering the encapsulation unit and the first organic layer.
An end portion of the first organic layer may disposed on the same plane as an end portion of the substrate.
An end portion of the second organic layer may be disposed on the same plane as an end portion of the substrate.
The first organic layer may include a plurality of organic patterns spaced apart from each other.
An end portion of an organic pattern at an outermost portion among the plurality of organic patterns may be disposed inside an end portion of the substrate.
An end portion of an organic pattern at an outermost portion among the plurality of organic patterns may be disposed on the same plane as an end portion of the substrate.
The encapsulation unit may include a first encapsulation layer covering the light emitting element; a foreign material cover layer on the first encapsulation layer; and a second encapsulation layer on the foreign material cover layer. The first organic layer may be disposed on the second encapsulation layer.
The first encapsulation layer and the second encapsulation layer may be in contact with each other under the first organic layer.
The display device may further include a dam configured to prevent overflow of the foreign material cover layer in the non-active area. The first organic layer may be disposed outside the dam.
A thickness of the first organic layer may be smaller than a thickness of the foreign material cover layer.
The first organic layer and the second organic layer may be formed of different materials.
The first organic layer may include photo acrylic, and the second organic layer may include an acrylic resin, an epoxy resin, or silicon oxycarbon.
A thickness of the first organic layer may be smaller than a thickness of the second organic layer.
The display device may further include a plurality of touch electrodes between the encapsulation unit and the second organic layer.

Although the exemplary aspects of the present disclosure have been described in detail with reference to the accompanying drawings, the present disclosure is not limited thereto and may be embodied in many different forms without departing from the technical concept of the present disclosure. Therefore, the exemplary aspects of the present disclosure are provided for illustrative purposes only but not intended to limit the technical concept of the present disclosure. The scope of the technical concept of the present disclosure is not limited thereto. Therefore, it should be understood that the above-described exemplary aspects are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate including an active area and a non-active area surrounding the active area;
a light emitting element in the active area;
an encapsulation unit covering the light emitting element;
a first organic layer disposed along a circumference of the substrate on the encapsulation unit in the non-active area; and
a second organic layer covering the encapsulation unit and the first organic layer.

2. The display device of claim 1, wherein an end portion of the first organic layer and an end portion of the substrate are disposed at a lateral edge of the display device.

3. The display device of claim 1, wherein an end portion of the second organic layer and an end portion of the substrate are disposed at a lateral edge of the display device.

4. The display device of claim 1, wherein the first organic layer includes at least a first organic pattern and a second organic pattern that separated from each other.

5. The display device of claim 4, wherein the first organic pattern is disposed outside the second organic pattern and an end portion of the first organic pattern is separated from a lateral edge from the display device.

6. The display device of claim 4, wherein an end portion of the first organic pattern is disposed at a lateral edge of the display device.

7. The display device of claim 1, wherein the encapsulation unit includes,
a first encapsulation layer covering the light emitting element;
a foreign material cover layer on the first encapsulation layer; and
a second encapsulation layer on the foreign material cover layer,
wherein the first organic layer is disposed on the second encapsulation layer.

8. The display device of claim 7, wherein the first encapsulation layer and the second encapsulation layer are in contact with each other under the first organic layer.

9. The display device of claim 7, further comprising:
a dam configured to prevent overflow of the foreign material cover layer in the non-active area,
wherein the first organic layer is disposed outside the dam.

10. The display device of claim 7, wherein a thickness of the first organic layer is smaller than a thickness of the foreign material cover layer.

11. The display device of claim 1, wherein the first organic layer and the second organic layer are formed of different materials.

12. The display device of claim 11, wherein the first organic layer includes photo acrylic and the second organic layer includes an acrylic resin, an epoxy resin, or silicon oxycarbon.

13. The display device of claim 1, wherein a thickness of the first organic layer is smaller than a thickness of the second organic layer.

14. The display device of claim 1, further comprising:
a plurality of touch electrodes between the encapsulation unit and the second organic layer.

15. The display device of claim 1, wherein the first organic layer is formed using a first process to fill a region between adjacent display devices on the substrate.

16. The display device of claim 15, wherein the second organic layer is formed using a second process to planarize all display devices on the substrate, wherein the second process is different from the first process.

17. The display device of claim 16, wherein the first process in an exposure process and the second process in an inkjet process.

18. A method of manufacturing a display device comprising:
forming a plurality of display devices on a substrate, wherein each display device includes a dam that forms a circumference for the display device;
depositing a first organic layer into a step region formed by dams of adjacent display devices;
forming a second organic layer over the plurality of substrates and the steps region; and
separating each display device based on the step region.

19. The method of claim 18, wherein depositing the first organic layer comprises an exposure process for a first material.

20. The method of claim 19, wherein forming the second organic layer comprises an inkjet process to cover an entire area of the substrate in a second material, wherein the second material is different from the first material.

21. The method of claim 18, wherein the first organic layer comprises at least a first organic pattern and a second organic pattern to increase a surface area of the first organic layer.

22. A display panel, comprising:
a substrate including an active area and a non-active area surrounding the active area;
light emitting elements in the active area;
an encapsulation unit disposed in the active area and a portion of the non-active area;
touch sensors disposed over the encapsulation unit and coupled to touch route lines, wherein the touch route lines are disposed in the non-active area; and
connection electrodes disposed in the non-active area on an insulating layer, wherein the connection electrodes are electrically connected to anodes of the light emitting elements in the active area,
wherein a connection electrode comprises a plurality of holes, and
wherein the touch route lines overlap the connection electrodes.

23. The display panel of claim 22, wherein the connection electrode extends in a first direction, and the plurality of holes are separated from each other in the first direction.

24. The display panel of claim 22, wherein the plurality of holes provide an escape path for gas in the insulating layer.

25. The display panel of claim 22, further comprising a vertical organic structure disposed at a circumference of the display panel.

26. The display panel of claim 25, wherein the vertical organic structure comprises a first organic structure and a second organic structure, and wherein the second organic structure is separated from a side surface of the display panel.

27. The display panel of claim 25, wherein the vertical organic structure and the insulating layer are formed using a first material.

28. The display panel of claim 22, wherein the touch route line is a first distance from the active area, the cathode is a second distance from the active area, and the second distance is greater than the first distance.

29. The display panel of claim 28, wherein the connection electrode is a third distance form the active area, and the third distance is greater than the second distance.

30. The display panel of claim 22, wherein the encapsulation unit includes a first encapsulation layer, a foreign material cover layer, and a second encapsulation layer.

31. The display panel of claim 30, wherein a thickness of the foreign material cover layer is thicker than a vertical organic structure disposed at a circumference of the display panel.

32. The display panel of claim 31, further comprising:
a dam disposed outside the foreign material cover layer, and
wherein the vertical organic structure is disposed outside the dam.

33. The display panel of claim 22, further comprising:
an organic layer covering the touch sensors and the touch route lines;
a polarizing plate on the organic layer; and
an adhesive layer between the organic layer and the polarizing plate.

34. The display panel of claim 22. further comprising:
a low potential power line electrically connected to the connection electrodes.
